(19) United States
(12) Patent Application Publication
(10) Pub. No.: US 2017/0125632 A1
(43) Pub. Date: May 4, 2017

(54) NITRIDE-SEMICONDUCTOR LIGHT-EMITTING ELEMENT

(71) Applicant: Sharp Kabushiki Kaisha, Sakai City, Osaka (JP)

(72) Inventor: Mayuko WATABE, Sakai City (JP)

(21) Appl. No.: 15/318,750

(22) PCT Filed: Jun. 3, 2015
(86) PCT No.: PCT/JP2015/066042

§ 371 Date: Dec. 14, 2016

(30) Foreign Application Priority Data
Jul. 4, 2014 (JP) 2014-138776

(51) Int. Cl. H01L 33/06; H01L 33/32

(52) U.S. Cl. CPC H01L 33/06; H01L 33/32

(57) ABSTRACT

A nitride-semiconductor light-emitting element includes an n-type nitride-semiconductor layer, a p-type nitride-semiconductor layer, and a light-emitting layer between the n-type nitride-semiconductor layer and the p-type nitride-semiconductor layer. The light-emitting layer has one or more quantum well layers and two or more barrier layers between which the quantum well layer(s) lie. A first barrier layer, which is the closest of the two or more barrier layers to the p-type nitride-semiconductor layer, has a thickness equal to or smaller than that of the barrier layer(s) different from the first. There is an undoped layer, a layer of a nitride semiconductor represented by a general formula AlₛGaₜInᵤN (0<s<1, 0<t<1, 0≦u<1, and s+t+u=1), between the first barrier layer and the p-type nitride-semiconductor layer.

### TECHNICAL FIELD

The present invention relates to a nitride-semiconductor light-emitting element.

### BACKGROUND ART

Nitrogen-containing Group III-V compound semiconducting materials (hereinafter referred to as “nitride-semiconductor materials”) have a band-gap energy that corresponds to the energy of light with infrared to ultraviolet wavelengths. This makes nitride-semiconductor materials useful in applications such as a component of light-emitting elements that emit light with infrared to ultraviolet wavelengths and a component of light-receiving elements that receive light with these ranges of wavelengths.

Nitride-semiconductor materials also have strong atomic forces in the nitride semiconductor, a high dielectric breakdown voltage, and a large saturated electron velocity. These make nitride-semiconductor materials useful as a component of electronic devices such as high-temperature-resistant and high-power radiofrequency transistors, too. Practically harmless to the environment, furthermore, nitride-semiconductor materials have been receiving attention as easy-to-handle materials.

For example, a nitride-semiconductor light-emitting element produced using an AlGaInN-based nitride semiconductor material emits short-wavelength light, such as blue light, with high efficiency. This means that combining this nitride-semiconductor light-emitting element with a phosphor gives a light emitter that emits white light. This light emitter, which now surpasses fluorescent lamps in terms of emission efficiency in some cases, is assuming the lead role in lighting. On the other hand, such light emitters are also expected to be further improved in emission efficiency and to make progress in energy conservation with the improved emission efficiency.

The emission of light from a nitride-semiconductor light-emitting element is through the recombination of holes and electrons. It is thus important to design n-type and p-type nitride semiconductor layers properly.

For example, PTL 1 describes a layer structure in which a blocking layer formed of p-type Al_{8.15}Ga_{0.85}N (Mg-doped) and a p-type contact layer formed of p-type GaN (Mg-doped) are stacked in this order on an active region.

PTL 2 discloses a nitride-semiconductor light-emitting element that includes an active layer that traps carriers and emits light, a carrier-blocking layer that confines the carriers to the active layer, and a 40-nm thick or thicker intermediate layer between the active and carrier-blocking layers. In this patent publication, it is disclosed that part of the intermediate layer is an AlₓGa₁₋ₓN (0≦x≦1) graded layer that has a band-gap energy gradient and is in contact with the carrier-blocking layer.

PTL 3 discloses that there is on an active layer an anti-cracking buffer layer with a grating structure across which the Al composition has an ascending gradient from 0 to 0.15.

### CITATION LIST

### Patent Literature

PTL 1: Japanese Unexamined Patent Application Publication No. 2009-130097

PTL 2: Japanese Unexamined Patent Application Publication No. 2005-150568

PTL 3: Japanese Unexamined Patent Application Publication No. 11-068158

### SUMMARY OF INVENTION

### Technical Problem

Attempts to increase the optical power of known nitride-semiconductor light-emitting element and lower their drive voltage, however, have resulted in the problem of impaired temperature characteristic because of insufficient control of the diffusion of p-type dopants into the light-emitting layer and the resulting excessive diffusion of the p-type dopants into the light-emitting layer. The term “impaired temperature characteristic” represents an increased relative loss of the performance (e.g., emission efficiency) of the nitride-semiconductor light-emitting element resulting from a temperature change.

A preferred way to prevent the impaired temperature characteristic, that is, to prevent p-type dopants from diffusing into the light-emitting layer, is to increase the Al composition of the AlGaN. Increasing the Al composition of the AlGaN, however, causes insufficient injection of holes into the active layer and thus leads to a loss of emission efficiency. Furthermore, too high an Al composition of the AlGaN leads to increased drive voltage. As this indicates, it is difficult for known nitride-semiconductor light-emitting element to combine improved temperature characteristic with improved emission efficiency and lowered drive voltage. The term “improved temperature characteristic” represents the possibility that the manufacturer can keep the relative loss of the performance of the nitride-semiconductor light-emitting element (e.g., emission efficiency) small even if the temperature changes.

Made in light of the foregoing, the present invention is intended to enhance the energy efficiency of nitride-semiconductor element by combining improved temperature characteristic with improved emission efficiency and lowered drive voltage and thereby to make progress in energy conservation.

### Solution to Problem

A nitride-semiconductor light-emitting element according to the present invention includes an n-type nitride-semiconductor layer, a p-type nitride-semiconductor layer, and a light-emitting layer between the n-type and p-type nitride-semiconductor layers. The light-emitting layer has one or more quantum well layers and two or more barrier layers, with the quantum well layer or layers lying between the barrier layers. A first barrier layer, which is the closest of the two or more barrier layers to the p-type nitride-semiconductor layer, has a thickness equal to or smaller than that of the barrier layer or layers different from the first barrier layer. There is an undoped layer between the first barrier layer and the p-type nitride-semiconductor layer. The undoped layer is a layer of a nitride semiconductor represented by a general formula AlₛGaₜInᵤN (0<s<1, 0<t<1, 0≦u<1, and s+t+u=1).

The undoped layer preferably has a greater band-gap energy than the first barrier layer. The undoped layer preferably includes a layer of a nitride semiconductor having an Al composition of 0.1 or more with a thickness of 1 nm or more. The undoped layer preferably includes two or more layers with different Al compositions. The undoped layer preferably has graded Al compositions across the thickness thereof.

In a first quantum well layer, which is the quantum well layer closest to the p-type nitride-semiconductor layer, the distance between the midpoint in the direction of the thickness of the first quantum well layer and the point in the first quantum well layer with a p-type dopant concentration of 1×10¹⁹ cm⁻³ is preferably 10 nm or less.

### Advantageous Effects of Invention

The nitride-semiconductor light-emitting element according to the present invention combines improved temperature characteristic with improved emission efficiency and lowered drive voltage and therefore will make progress in energy conservation.

### BRIEF DESCRIPTION OF DRAWINGS

FIG. 1 is a cross-section of a nitride-semiconductor light-emitting element according to an embodiment of the present invention.

FIG. 2 is an energy band diagram that schematically illustrates the band structure of a nitride-semiconductor light-emitting element according to an embodiment of the present invention.

FIG. 3 is an energy band diagram that schematically illustrates the band structure of a nitride-semiconductor light-emitting element according to an embodiment of the present invention.

FIG. 4 is an energy band diagram that schematically illustrates the band structure of a nitride-semiconductor light-emitting element according to an embodiment of the present invention.

FIGS. 5 (a) and (b) are cross-sections of a first quantum well layer.

FIG. 6 is a graph of results obtained in

### EXAMPLES

FIG. 7 is a graph of results obtained in Examples.

FIG. 8 is a graph of results obtained in Examples.

FIG. 9 is an energy band diagram that schematically illustrates the band structure of the nitride-semiconductor light-emitting element of Example 14.

### DESCRIPTION OF EMBODIMENTS

The following describes the present invention with reference to drawings. In the drawings of the present invention, the same reference numerals refer to the same or corresponding parts. To make the drawings clear and simple, the proportions of dimensions such as lengths, widths, thicknesses, and depths are not to scale and do not represent actual proportions.

### [Structure of the Nitride-Semiconductor Light-Emitting Element]

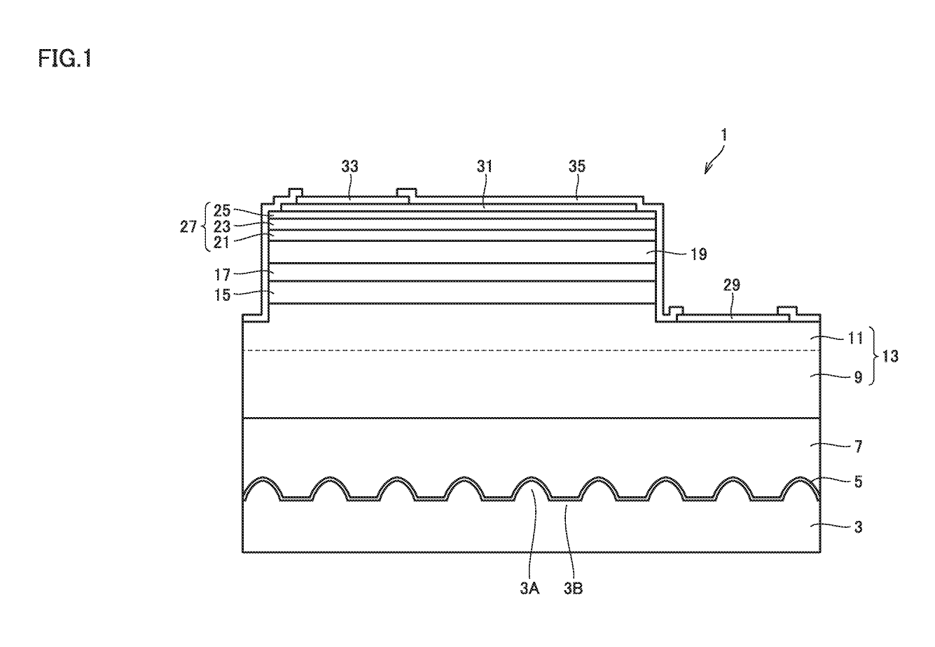

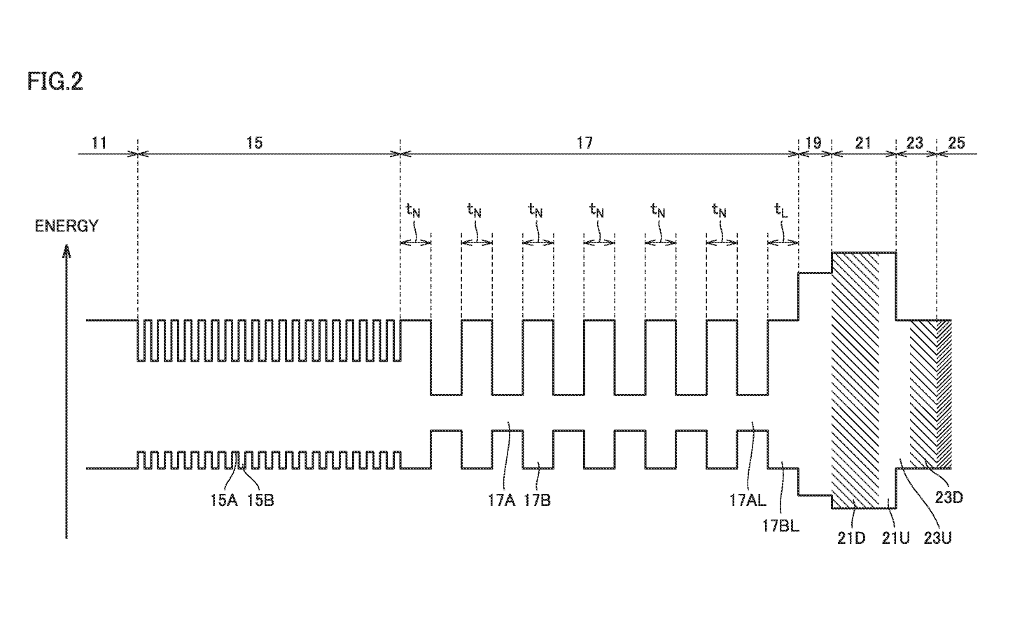

FIG. 1 is a cross-section of a nitride-semiconductor light-emitting element according to an embodiment of the present invention. FIGS. 2 to 4 are energy band diagrams that schematically illustrate the band structures of nitride-semiconductor light-emitting element according to this embodiment. In FIGS. 2 to 4, the shading indicates regions containing a p-type dopant. A higher density of the lines indicates a higher p-type dopant concentration.

The nitride-semiconductor light-emitting element 1 has, on the top surface of a substrate 3, a buffer layer 5, an underlying layer 7, an n-type nitride semiconductor layer 13, a superlattice layer 15, a light-emitting layer 17, an undoped layer 19, and a p-type nitride semiconductor layer 27 in this order. Such a nitride-semiconductor light-emitting element 1 combines improved temperature characteristic with improved emission efficiency and lowered drive voltage and therefore will make progress in energy conservation.

The term “temperature characteristic” represents the proportion of the performance of the nitride-semiconductor light-emitting element 1 at room temperature to that of the nitride-semiconductor light-emitting element 1 at high temperatures. An example is the proportion of the emission efficiency of the nitride-semiconductor light-emitting element 1 at room temperature to that of the nitride-semiconductor light-emitting element 1 at high temperatures. Proportions closer to 1 (or 100%) indicate “improved temperature characteristic of the nitride-semiconductor light-emitting element 1” or “the possibility of enhanced temperature characteristic of the nitride-semiconductor light-emitting element 1.”

The n-type nitride semiconductor layer 13 has a first n-type nitride semiconductor layer 9 on the top surface of the underlying layer 7 and a second n-type nitride semiconductor layer 11 on the top surface of the first n-type nitride semiconductor layer 9. The p-type nitride semiconductor layer 27 has a first p-type nitride semiconductor layer 21 on the top surface of the undoped layer 19, a second p-type nitride semiconductor layer 23 on the top surface of the first p-type nitride semiconductor layer 21, and a third p-type nitride semiconductor layer 25 on the top surface of the second p-type nitride semiconductor layer 23. The n-type nitride semiconductor layer 13 may be composed of any number of layers. For example, the n-type nitride semiconductor layer 13 can be a single layer. The same applies to the p-type nitride semiconductor layer 27.

There is an n-side electrode 29 on the exposed surface of the second n-type nitride semiconductor layer 11. There is a p-side electrode 33 on the top surface of the third p-type nitride semiconductor layer 25 with a transparent electrode 31 therebetween. The top side of the nitride-semiconductor light-emitting element 1 is covered with a transparent protection film 35, but the top surfaces of the n-side electrode 29 and the p-side electrode 33 are exposed, not covered with the transparent protection film 35.

### <Substrate>

The substrate 3 may be, for example, an insulating substrate, such as a sapphire substrate, or may alternatively be a conductive substrate, such as GaN, SiC, or ZnO. The substrate 3 can have any thickness, but preferably 60 μm or more and 300 μm or less. Although in FIG. 1 the top surface of the substrate 3 has projections 3A formed as curved surfaces alternating with recesses 3B formed as flat surfaces, the top surface of the substrate 3 may be flat.

### <Buffer Layer>

The buffer layer 5 is preferably an Alₐ₀Ga_{b0}N (0≦a0≦1, 0≦b0≦1, and a0+b0=1), more preferably an AlN or AlON layer (containing 0.2 to 5 at % O), even more preferably an AlON layer formed by a known sputtering process. When the buffer layer 5 is an AlON layer formed by a known sputtering process, the buffer layer 5 extends normal to the growth surface (top surface) of the substrate 3. This ensures the resulting buffer layer 5 is an aggregate of columnar crystals with uniform grain sizes. The buffer layer 5 can have any thickness, but preferably 5 nm or more and 100 nm or less, more preferably 10 nm or more and 50 nm or less.

### <Underlying Layer>

The underlying layer 7 is preferably an Alₐ₁Ga_{b1}In_{c1}N (0≦a1≦1, 0≦b1≦1, 0≦c1, and a1+b1+c1=1) layer, more preferably an Alₐ₁Ga_{b1}N (0≦a1≦1, 0≦b1≦1, and a1+b1=1) layer, even more preferably a GaN layer. When the underlying layer 7 is a GaN layer, crystallographic defects in the buffer layer 5, such as dislocations, are likely to be looped near the interface between the buffer layer 5 and the underlying layer 7. This prevents the crystallographic defects from being carried over from the buffer layer 5 into the underlying layer 7.

The underlying layer 7 preferably has a first underlying layer on the top surface of the buffer layer 5, a second underlying layer on the top surface of the first underlying layer, and a third underlying layer on the top surface of the second underlying layer. Such an underlying layer 7 is formed as follows. First, a first underlying layer is grown. The temperature of the substrate 3 is lowered, and a second underlying layer is grown. The second underlying layer is grown three-dimensionally; therefore, the resulting second underlying layer has facets. Then the temperature of the substrate 3 is increased, and a third underlying layer is grown. The third underlying layer is grown laterally; therefore, the top surface of the resulting third underlying layer (i.e., the top surface of the underlying layer 7) is flat. This way of forming the underlying layer 7 prevents any dislocation from reaching the light-emitting layer 17 by making the dislocation turn at a facet of the second underlying layer.

The underlying layer 7 may contain an n-type dopant. Any n-type dopant in the underlying layer 7, however, can cause the wafer (the substrate for the growth of nitride semiconductor layers) to be greatly warped by increasing the thickness of n-doped layers in the nitride-semiconductor light-emitting element 1. A great warp in the wafer can cause the temperature vary within the wafer plane during the growth of the nitride-semiconductor light-emitting layer. The great warp in the wafer may also affect the yield of the production of the nitride-semiconductor light-emitting element 1 by influencing the steps of forming components such as the n-side electrode 29. Making the underlying layer 7 free of n-type dopants prevents these problems and gives the underlying layer 7 a higher crystallographic quality. It is thus preferred that the underlying layer 7 be free of n-type dopants.

Such an underlying layer 7 can have any thickness, but preferably 1 μm or more and 12 μm or less.

### <N-Type Nitride-Semiconductor Layers>

Each of the first n-type nitride semiconductor layer 9 and the second n-type nitride semiconductor layer 11 is preferably an n-doped Alₐ₂Ga_{b2}In_{c2}N (0≦a2≦1, 0≦b2≦1, 0≦c2≦1, and a2+b2+c2=1) layer, more preferably an n-doped Alₐ₂Ga₁₋ₐ₂N (0≦a2≦1, even more preferably 0≦a2≦0.5, still even more preferably 0≦a2≦0.1) layer.

The n-type dopant can be of any kind, but preferably an element such as Si, P, As, or Sb, more preferably Si. In each of the first n-type nitride semiconductor layer 9 and the second n-type nitride semiconductor layer 11 the n-type dopant can be present in any concentration, but preferably 1 ×10¹⁸ cm⁻³ or more and 2×10¹⁹ cm⁻³ or less. Each of the first n-type nitride semiconductor layer 9 and the second n-type nitride semiconductor layer 11 can have any thickness, but preferably 0.5 μm or more and 10 μm or less.

The first n-type nitride semiconductor layer 9 and the second n-type nitride semiconductor layer 11 may share the same composition or may have different compositions. The thickness may be the same or vary from one to the other.

### <Superlattice Layer>

A superlattice layer is a layer in which different crystal lattices overlap one another to form a periodic structure longer than the primitive unit cells. In the superlattice layer 15, as illustrated in FIGS. 2 to 4, first semiconductor layers 15A and second semiconductor layers 15B are alternately stacked to build a superlattice structure, and its periodic structure is longer than the primitive unit cell of the semiconductor material making up the first semiconductor layers 15A and that of the semiconductor material making up the second semiconductor layers 15B. The superlattice layer 15 can be of any thickness per cycle, but preferably 1 nm or more and 7 nm or less.

There may be any number of first semiconductor layers 15A and any number of second semiconductor layers 15B in the superlattice layer 15. It is preferred to determine the number of first semiconductor layers 15A and that of second semiconductor layers 15B in the superlattice layer 15 so that the superlattice layer 15 will have a thickness of 50 nm or more and 500 nm or less. The superlattice layer 15 plays the role of producing V-pits. When the thickness of the superlattice layer 15 is 50 nm or more, V-pits of a desired size are produced with a desired areal density. This further enhances the emission efficiency of the nitride-semiconductor light-emitting element 1. When the thickness of the superlattice layer 15 is 500 nm or less, the light-emitting layer 17 has better surface planarity (planarity of the top surface of the light-emitting layer 17) because the V-pits do not outgrow. This increases the optical power of the nitride-semiconductor light-emitting element 1.

The superlattice structure of the superlattice layer 15 may be formed by a first semiconductor layer 15A, a second semiconductor layer 15B, and one or more semiconductor layers different from the first semiconductor layer 15A and the second semiconductor layer 15B stacked in order.

### (First Semiconductor Layers)

Each first semiconductor layer 15A is preferably an n-doped Alₐ₃Ga_{b3}In_{c3}N (0≦a3≦1, 0≦b3≦1, 0≦c3≦1, and a3+b3+c3=1) layer, more preferably an n-doped GaN layer. The concentration of the n-type dopant in each first semiconductor layer 15A is preferably 1×10¹⁸ cm⁻³ or more and 5×10¹⁹ cm⁻³ or less.

Each first semiconductor layer 15A can have any thickness, but preferably 0.5 nm or more and 30 nm or less, more preferably 1 nm or more and 10 nm or less. When the thickness of each first semiconductor layer 15A is 0.5 nm or more, each first semiconductor layer 15A is thicker than one atomic layer. The resulting uniformity in thickness of the first semiconductor layers 15A gives the light-emitting layer 17 a higher crystallographic quality. This further enhances the emission efficiency of the nitride-semiconductor light-emitting element 1.

Typically, the first semiconductor layers 15A are doped with an n-type dopant in a concentration lower than in the n-type nitride semiconductor layers at a temperature lower than the temperature at which the n-type nitride semiconductor layers are grown. When the thickness of each first semiconductor layer 15A is 30 nm or less, improved planarity of the first semiconductor layers 15A gives the light-emitting layer 17 a higher crystallographic quality. This further enhances the emission efficiency of the nitride-semiconductor light-emitting element 1.

### (Second Semiconductor Layers)

Each second semiconductor layer 15B preferably has a greater band-gap energy than the first semiconductor layers 15A, more preferably being an Alₐ₄Ga_{b4}In_{c4}N (0≦a4≦1, 0≦b4≦1, 0≦c4≦1, and a4+b4+c4=1) layer, even more preferably an Alₐ₄Ga_{b4}In_{c4}N (a4=0, 0≦b≦1, 0≦c4≦1, and a4+b4+c4=1) layer. Each second semiconductor layer 15B may contain an n-type dopant.

Each second semiconductor layer 15B can have any thickness, but preferably 0.5 nm or more and 30 nm or less, more preferably 1 nm or more and 10 nm or less. When the thickness of each second semiconductor layer 15B is 0.5 nm or more, each second semiconductor layer 15B is thicker than one atomic layer. The resulting uniformity in thickness of the second semiconductor layers 15B gives the light-emitting layer 17 a higher crystallographic quality. This further enhances the emission efficiency of the nitride-semiconductor light-emitting element 1. When the thickness of each second semiconductor layer 15B is 30 nm or less, the second semiconductor layers 15B do not require long periods to grow, thereby improving productivity in the manufacture of the nitride-semiconductor light-emitting element 1.

### <Light-Emitting Layer>

The light-emitting layer 17 has the multi-quantum-well structure, a stack of quantum well layers alternating with barrier layers. Specifically, the light-emitting layer 17 is a stack of quantum well layers alternating with barrier layers in which the quantum well layers lie between the barrier layers.

In the following, the quantum well layer closest to the p-type nitride semiconductor layer 27 is referred to as “the first quantum well layer 17AL” and the quantum well layers different from the first quantum well layer 17AL as “secondary quantum well layers 17A” for the sake of simplicity (FIGS. 2 to 4). The first quantum well layer 17AL and the secondary quantum well layers 17A are collectively referred to as “quantum well layers.” If the light-emitting layer 17 has only one quantum well layer, this quantum well layer is the first quantum well layer 17AL.

Likewise, the barrier layer closest to the p-type nitride semiconductor layer 27 is referred to as “the first barrier layer 17BL” and the barrier layers different from the first barrier layer 17BL as “secondary barrier layers 17B” (FIGS. 2 to 4). The first barrier layer 17BL and the secondary barrier layers 17B are collectively referred to as “barrier layers.”

### (Quantum Well Layers)

Each quantum well layer is preferably an undoped InₓGa₍₁₋ₓ₎N (0<x≦1) layer, more preferably an undoped InₓGa₍₁₋ₓ₎N (0<x≦0.5) layer. When the quantum well layers are free of n-type dopants, improved planarity of the light-emitting layer 17 gives the p-type nitride semiconductor layer 27 a higher crystallographic quality.

Each quantum well layer can have any thickness, but preferably 2 nm or more and 15 nm or less. When the thickness of each quantum well layer is 2 nm or more and 15 nm or less, the nitride-semiconductor light-emitting element 1 achieves further enhanced emission efficiency and even lower drive voltage.

There may be any number of quantum well layers. It is preferred to use one or more quantum well layers, more preferably two or more (multiple). The use of two or more (multiple) quantum well layers leads to a lower current density in the light-emitting layer 17, ensuring that the light-emitting layer 17 produces only a small amount of heat even if the nitride-semiconductor light-emitting element 1 is driven with a great deal of current. The carriers no longer overflow from the light-emitting layer 17, and this prevents non-radiative recombination from occurring in any layer different from the light-emitting layer 17. As a result, the emission efficiency of the nitride-semiconductor light-emitting element 1 is further enhanced.

When two or more (multiple) quantum well layers are used, the quantum well layers may vary in thickness. For example, it is preferred that the first quantum well layer 17AL be thicker than the secondary quantum well layer(s) 17A. This provides increased optical power at room temperature.

It is also preferred that the secondary quantum well layer 17A next to the first quantum well layer 17AL be thicker than any other secondary quantum well layer 17A. This gives the nitride-semiconductor light-emitting element 1 further enhanced temperature characteristic.

Furthermore, the thickness of each quantum well layer may be adjusted to make the individual layers emit light with desired wavelengths for emission of white lite from the nitride-semiconductor light-emitting element 1.

FIGS. 5 (a) and (b) are cross-sections of the first quantum well layer 17AL. In the first quantum well layer 17AL, it is preferred that the distance d₁ between the midpoint in the direction of the thickness of the first quantum well layer 17AL (point M) and the point in the first quantum well layer 17AL with a p-type dopant concentration of 1×10¹⁹ cm⁻³ (point X) (hereinafter also referred to as “the p-dopant diffusion distance d₁”) be 10 nm or less. This translates into successful limitation of the diffusion of the p-type dopant from the p-type nitride semiconductor layer 27 into the light-emitting layer 17 (hereinafter referred to as “p-dopant diffusion”). The p-dopant diffusion distance d₁ is the distance between points M and X in the direction of the thickness of the first quantum well layer 17AL.

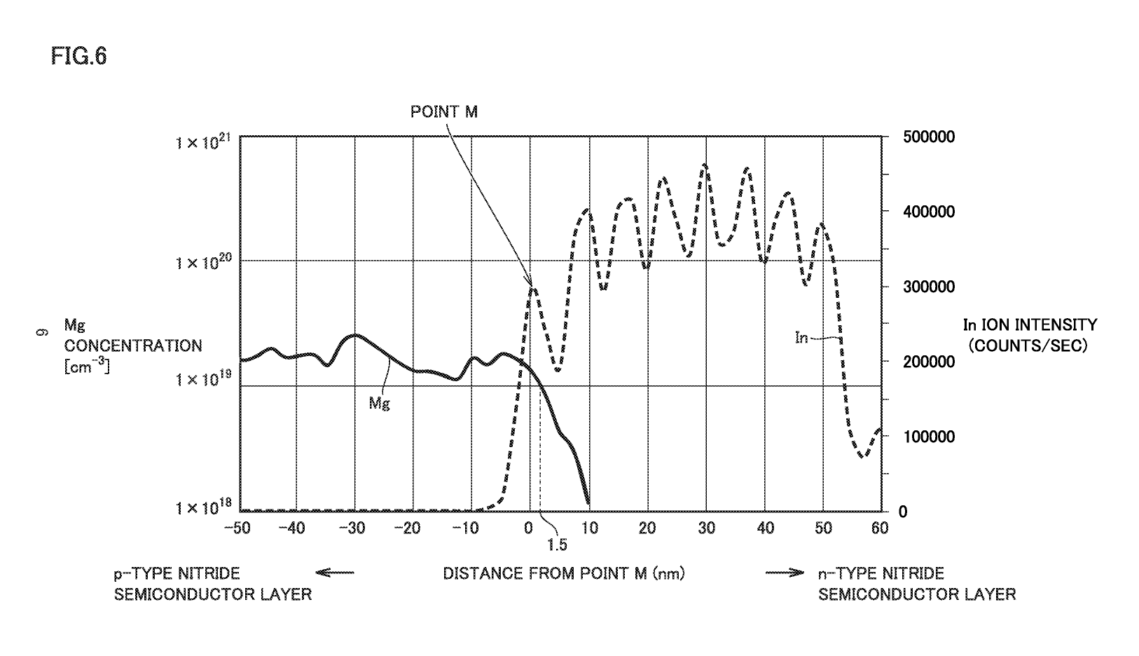

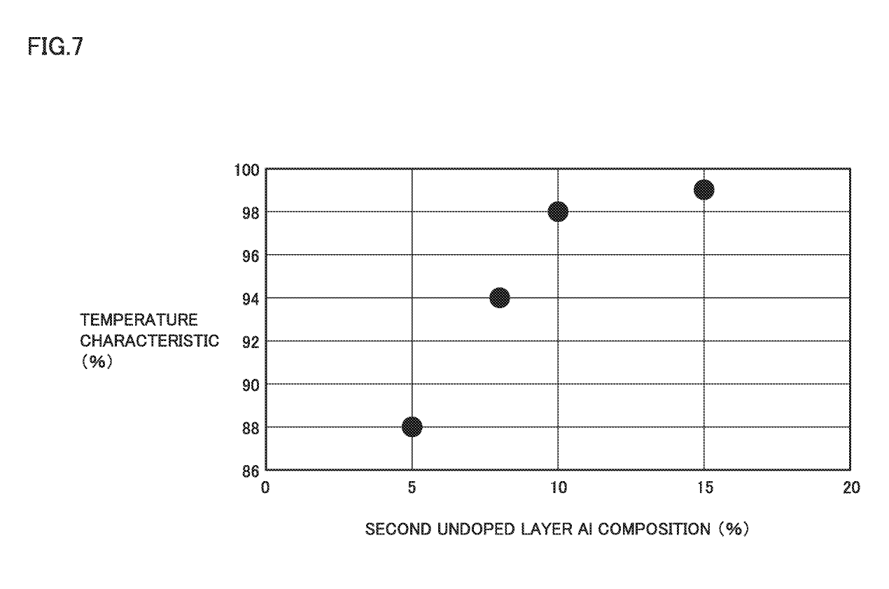

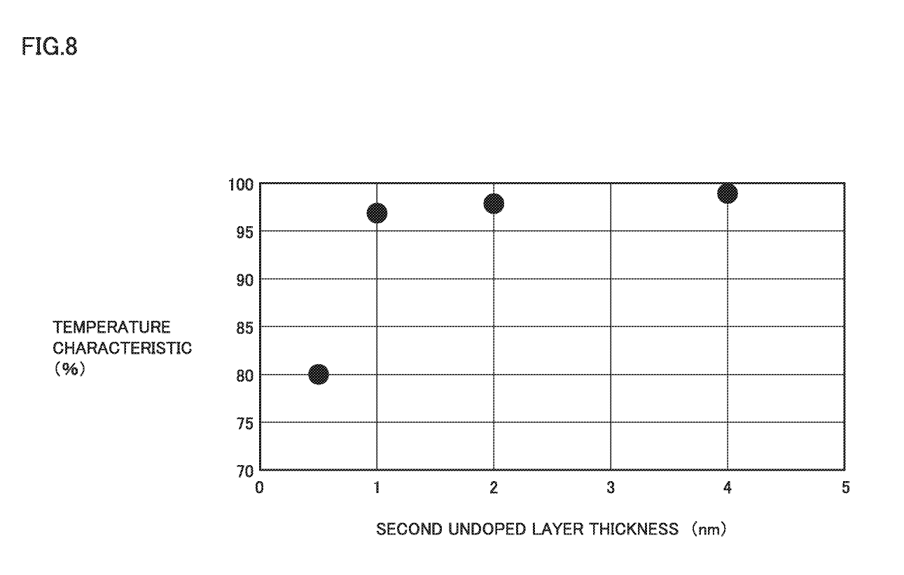

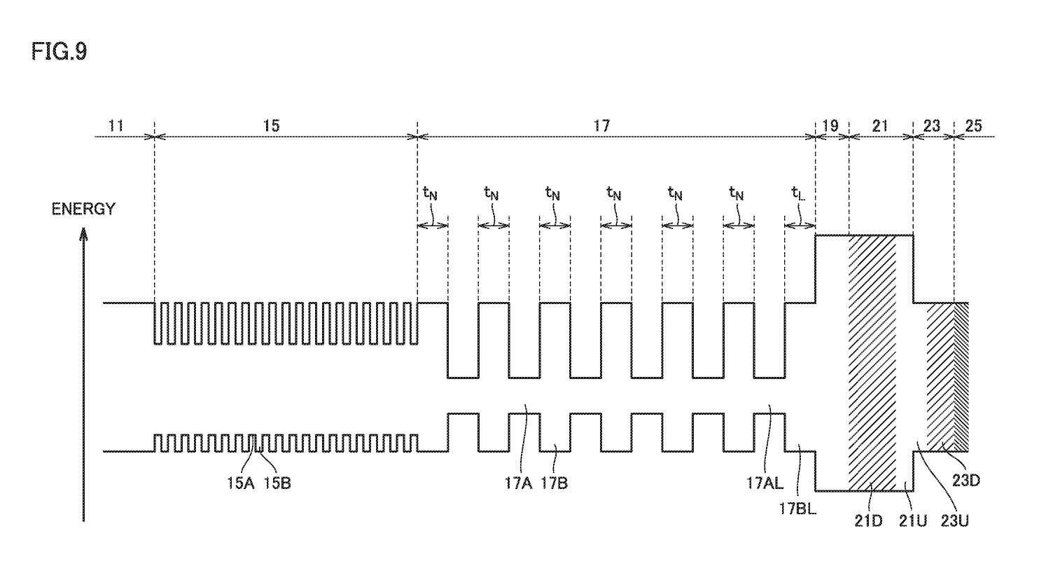

As is presented in FIG. 6, the p-dopant diffusion distance d₁ can be measured using SIMS (Secondary Ion Mass Spectrometry). FIG. 6 illustrates Mg and In concentration profiles of the nitride-semiconductor light-emitting element of Example 1 (described hereinafter) as measured using SIMS. Point M corresponds to the position of the first In ion intensity peak of the first quantum well layer 17AL on the p-type nitride semiconductor layer 27 side. In FIG. 6, point M is at 0 on the x-axis and the p-dopant diffusion distance d₁ is the x-value at the point where the Mg concentration is 1×10¹⁹ cm⁻³ (point X). The expression “the p-dopant diffusion distance d₁ is 10 nm or less” in FIG. 6 means that the x-value at point X is in the range of −10 nm to +10 nm. In FIG. 6, the n-type nitride semiconductor layer 13 side with respect to point M is designated plus (positive), and the p-type nitride semiconductor layer 27 side with respect to point M is designated minus (negative).

A p-dopant diffusion distance d₁ of −10 nm or more and +10 nm or less, which means successful control of the p-dopant diffusion distance d₁ to its optimum range, ensures further improved temperature characteristic combined with even better emission efficiency and even lower drive voltage. A p-dopant diffusion distance d₁ beyond +10 nm on the plus side, which indicates excessive diffusion of the p-type dopant, can result in impaired temperature characteristic. A p-dopant diffusion distance d₁ beyond −10 nm on the minus side, which translates into insufficient diffusion of the p-type dopant, can cause a loss of emission efficiency or an increase in drive voltage.

When the first quantum well layer 17AL has a p-type dopant concentration of 1×10¹⁹ cm⁻³ at a particular point in the direction of its thickness as in FIG. 5 (a), the p-dopant diffusion distance d₁ is the distance between points M and X in the direction of the thickness of the first quantum well layer 17AL.

When the first quantum well layer 17AL has a p-type dopant concentration of 1×10¹⁹ cm⁻³ over a certain range in the direction of its thickness as in FIG. 5 (b) (when there is layer X), the p-dopant diffusion distance d₁ is the shortest distance between layer X and point M in the direction of the thickness of the first quantum well layer 17AL (the distance between points X and M as in FIG. 5 (b)).

Although FIGS. 5 (a) and 5 (b) illustrate cases in which point X is on the p-type nitride semiconductor layer 27 side with respect to point M, point X can be on the n-type nitride semiconductor layer 13 side with respect to point M in other cases.

### (Barrier Layers)

Each barrier layer has a greater band-gap energy than the quantum well layers, preferably being an Al_{y}Ga_{z}In(_{1-y-z})N (0≦y<1 and 0<z≦1) layer.

The thickness of each barrier layer is preferably 20 nm or less, more preferably 1.5 nm or more and 10 nm or less. When the thickness of each barrier layer is 1.5 nm or more, improved planarity of the barrier layers gives the barrier layers a higher crystallographic quality. This further enhances the emission efficiency of the nitride-semiconductor light-emitting element 1. When the thickness of the barrier layers is 20 nm or less, carriers injected into the light-emitting layer 17 are diffused within the light-emitting layer 17. This gives the nitride-semiconductor light-emitting element 1 even lower drive voltage and further enhanced emission efficiency.

The barrier layers may be undoped, or may alternatively contain an n-type or p-type dopant.

There may be any number of barrier layers. It should be noted that the number of barrier layers is the number of quantum wall layers plus one because the quantum wall layers lie between the barrier layers.

As mentioned hereinafter, the thickness t_{L} of the first barrier layer 17BL is equal to or smaller than the thickness t_{N} of the secondary barrier layers 17B. The secondary barrier layers 17B may vary in thickness.

### <Undoped Layer>

The undoped layer 19, lying between the first barrier layer 17BL and the p-type nitride semiconductor layer 27, is a layer of a nitride semiconductor represented by a general formula AlₛGaₜInᵤN (0<s<1, 0<t<1, 0≦u<1, and s+t+u=1). Having a greater band-gap energy than the first barrier layer 17BL, such an undoped layer 19 effectively prevents the diffusion of the p-type dopant. This effectively enhances the temperature characteristic of the nitride-semiconductor light-emitting element 1. A way to give the undoped layer 19 a band-gap energy greater than that of the first barrier layer 17BL is to make the Al composition of the undoped layer 19 higher than that of the first barrier layer 17BL.

The term “undoped layer” represents a layer to which no n-type or p-type dopant has been intentionally added thereto.

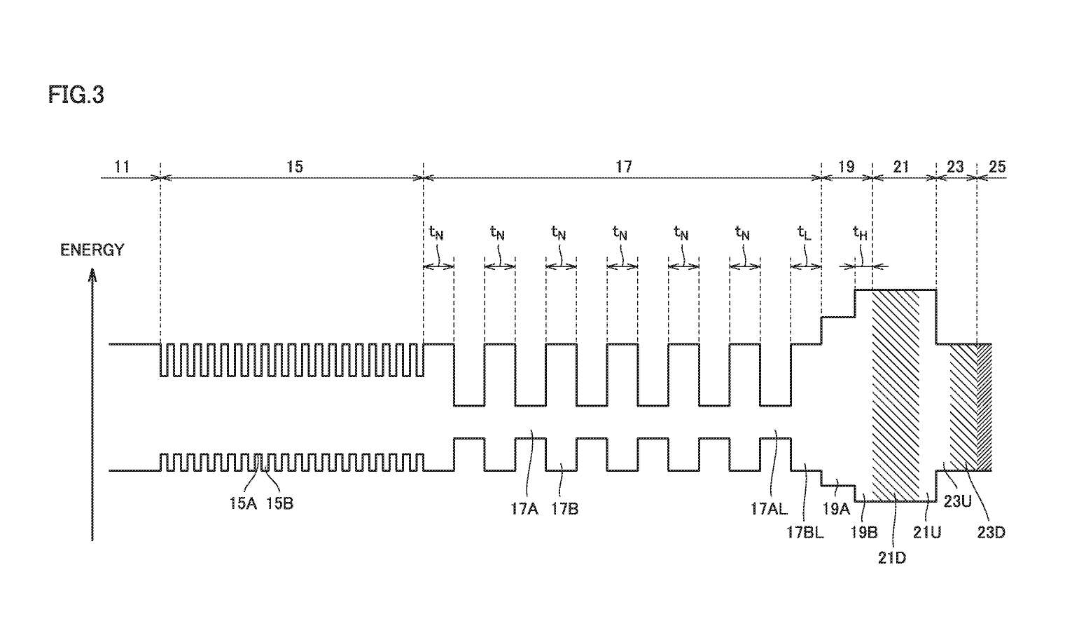

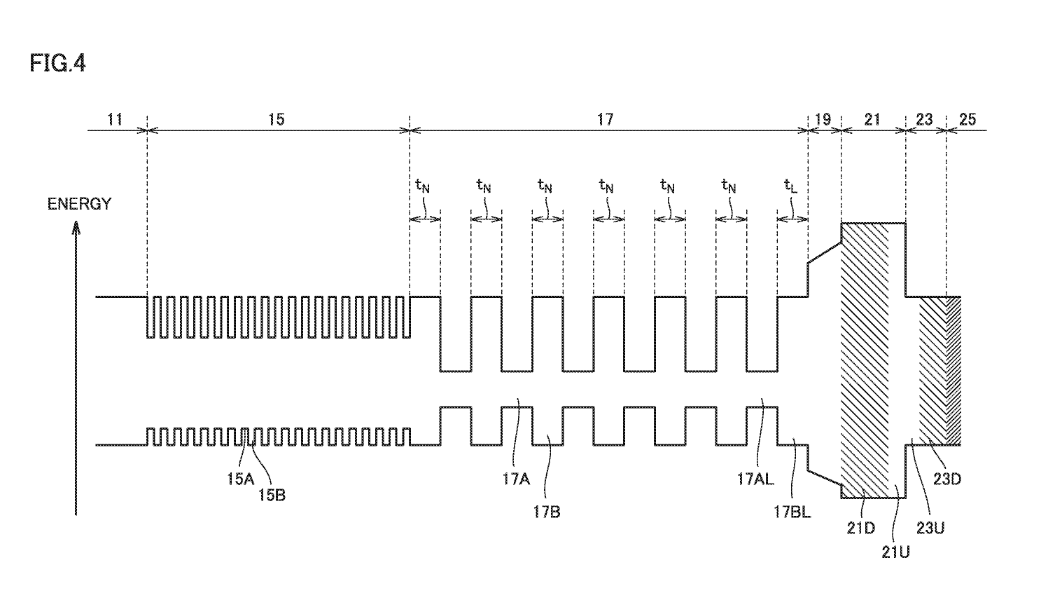

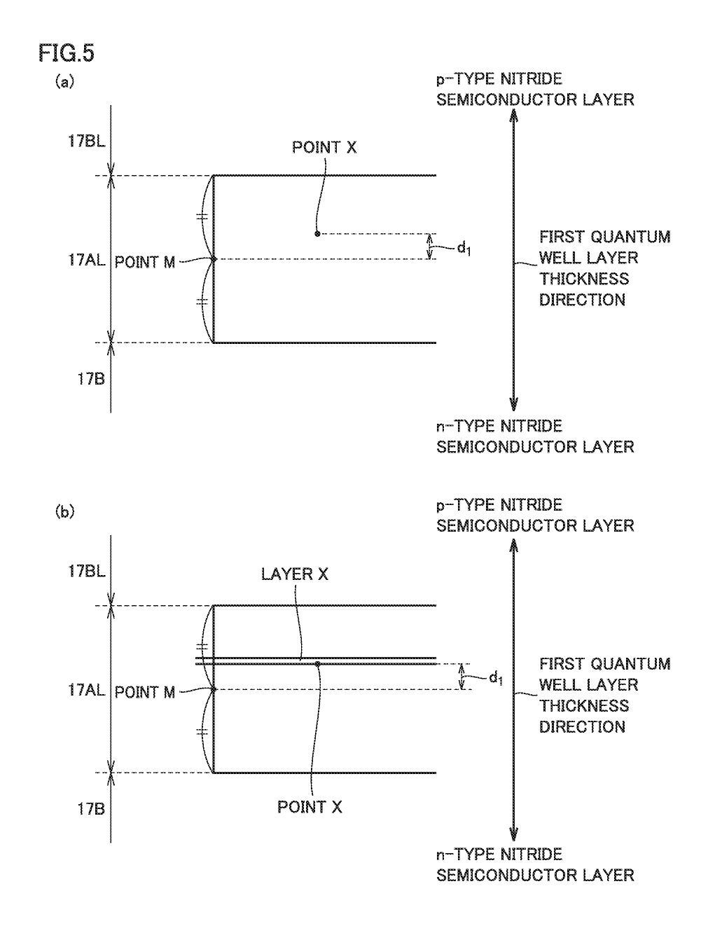

When the undoped layer 19 has two or more band-gap energies (e.g., FIG. 3 or 4), the expression “the undoped layer 19 has a greater band-gap energy than the first barrier layer 17BL” means that the smallest band-gap energy among the layers that form the undoped layer 19 (in FIG. 3, the band-gap energy of the first undoped layer 19A) is greater than that of the first barrier layer 17BL.

The structure of such an undoped layer 19 is, for example, as illustrated in FIGS. 2 to 4.

The undoped layer 19 in FIG. 2 is a single layer that has uniform band-gap energy throughout. Such an undoped layer 19 is preferably a layer of a nitride semiconductor represented by Alₛ₁Gaₜ₁Inᵤ₁N (0<s1≦0.4, 0.6≦t1<1, 0≦u1≦0.1, and s1+t1+u1=1), more preferably a layer of a nitride semiconductor represented by Alₛ₁Gaₜ₁Inᵤ₁N (0.1≦s1 0.3, 0.7≦t1≦0.9, 0 ≦u1≦0.1, and s1+t1+u1=1).

The thickness of the undoped layer 19 in FIG. 2 is preferably 0.5 nm or more and 20 nm or less. When the thickness of the undoped layer 19 is 0.5 nm or more, the diffusion of the p-type dopant is effectively prevented, and this gives the nitride-semiconductor light-emitting element 1 even better temperature characteristic. When the thickness of the undoped layer 19 is 20 nm or less, the drive voltage of the nitride-semiconductor light-emitting element 1 is further reduced. It is more preferred that the undoped layer 19 in FIG. 2 have a thickness of 1 nm or more and 15 nm or less.

The diffusion of the p-type dopant is more successfully prevented with increasing Al composition of the undoped layer 19. The p-dopant diffusion distance d₁ can become shorter with increasing thickness of the undoped layer 19. An increase in the Al composition of the undoped layer 19 or in the thickness of the undoped layer 19, however, can cause a rise of drive voltage. In order to make it easy to prevent the diffusion of the p-type dopant and optimize (shorten or extend) the p-dopant diffusion distance d₁ while avoiding any increase in drive voltage, it is preferred to use the undoped layer 19 illustrated in FIG. 3 or 4 rather than that in FIG. 2.

The undoped layer 19 in FIG. 3 has a first undoped layer 19A on the top surface of the first barrier layer 17BL and a second undoped layer (a layer of a nitride semiconductor having an Al composition of 0.1 or more with a thickness of 1 nm or more) 19B on the top surface of the first undoped layer 19A. The second undoped layer 19B has a greater Al composition than the first undoped layer 19A and therefore has a greater band-gap energy than the first undoped layer 19A.

In the undoped layer 19 in FIG. 3, the second undoped layer 19B makes the prevention of the diffusion of the p-type dopant more effective, and the first undoped layer 19A optimizes the p-dopant diffusion distance d₁ (e.g., the p-dopant diffusion distance d₁ can be adjusted to 10 nm or less). This prevents any voltage rise at the undoped layer 19, thereby preventing the drive voltage from increasing.

The first undoped layer 19A is preferably a layer of a nitride semiconductor represented by Alₛ₂Gaₜ₂Inᵤ₂N (0<s2≦0.4, 0.6≦t2<1, 0≦u2≦0.1, and s2+t2+u2=1), more preferably a layer of a nitride semiconductor represented by Alₛ₂Gaₜ₂Inᵤ₂N (0.001≦s2≦0.3, 0.7≦t2≦0.999, 0≦u2≦0.1, and s2+t2+u2=1).

The thickness of the first undoped layer 19A is preferably 0.5 nm or more and 20 nm or less. When the thickness of the first undoped layer 19A is 0.5 nm or more, the p-dopant diffusion distance d₁ is short; for example, the p-dopant diffusion distance d₁ is 10 nm or less. This further enhances the temperature characteristic of the nitride-semiconductor light-emitting element 1. When the thickness of the first undoped layer 19A is 20 nm or less, the drive voltage of the nitride-semiconductor light-emitting element 1 is further reduced. It is more preferred that the first undoped layer 19A have a thickness of 1 nm or more and 15 nm or less.

The second undoped layer 19B, which has a greater band-gap energy than the first undoped layer 19A, prevents the diffusion of the p-type dopant on the p-type nitride semiconductor layer 27 side (i.e., at a distance from the light-emitting layer 17), thereby giving the nitride-semiconductor light-emitting element 1 even better temperature characteristic. It also prevents band bending at the first barrier layer 17BL or the quantum well layers and thus increases the probability of radiative recombination, thereby making emission efficiency even higher. The second undoped layer 19B is preferably a layer of a nitride semiconductor represented by Alₛ₃Gaₜ₃Inᵤ₃N (0.1≦s3≦0.4, 0.6≦t3≦0.9, 0≦u3≦0.1, and s3+t3+u3=1), more preferably a layer of a nitride semiconductor represented by Alₛ₃Gaₜ₃Inᵤ₃N (0.12≦s3≦0.3, 0.7≦t3≦0.88, 0≦u3≦0.1, and s3+t3+u3=1).

The thickness t_{H} of the second undoped layer 19B is preferably 1 nm or more and 20 nm or less. When the thickness t_{H} of the second undoped layer 19B is 1 nm or more, the diffusion of the p-type dopant is effectively prevented, and this gives the nitride-semiconductor light-emitting element 1 even better temperature characteristic. When the thickness t_{H} of the second undoped layer 19B is 20 nm or less, the drive voltage of the nitride-semiconductor light-emitting element 1 is less likely to increase. It is more preferred that the second undoped layer 19B have a thickness t_{H} of 1 nm or more and 10 nm or less.

The undoped layer 19 in FIG. 3 may have one or more additional undoped layers different from the first undoped layer 19A and the second undoped layer 19B.

The undoped layer 19 in FIG. 4 has graded Al compositions across the thickness of the undoped layer 19, and therefore has graded band-gap energies across the thickness of the undoped layer 19.

As stated hereinafter, the band bending due to a piezoelectric field at the first barrier layer 17BL is smaller than that at the secondary barrier layers 17B when the thickness t_{L} of the first barrier layer 17BL is equal to or smaller than the thickness t_{N} of the secondary barrier layers 17B. When the undoped layer 19 has graded Al compositions across the thickness of the undoped layer 19, however, the band bending due to a piezoelectric field at the first barrier layer 17BL is even smaller than that at the secondary barrier layers 17B. This makes the injection of holes from the p-type nitride semiconductor layer 27 into the first quantum well layer 17AL and the secondary quantum well layers 17A even more efficient, giving the nitride-semiconductor light-emitting element 1 further improved emission efficiency and even lower drive voltage. In addition to this, the presence of a high-Al-composition region in the undoped layer 19 makes the prevention of the diffusion of the p-type dopant more effective, further enhancing the temperature characteristic.

The expression “the band bending due to a piezoelectric field at the first barrier layer 17BL is smaller than that for the secondary barrier layers 17B” means that at the first barrier layer 17BL, the difference between the band energy on the light-emitting layer 17 side and that on the undoped layer 19 side is smaller than at the secondary barrier layers 17B.

The expression “graded Al compositions across the thickness of the undoped layer 19” represents a monotonic increase in Al composition in the undoped layer 19 from the light-emitting layer 17 toward the p-type nitride semiconductor layer 27. Preferably, the minimum Al composition in the undoped layer 19 is 0 or more and 0.3 or less, and the maximum Al composition in the undoped layer 19 is 0.12 or more and 0.4 or less. More preferably, the minimum Al composition in the undoped layer 19 is 0.08 or more and 0.3 or less, and the maximum Al composition in the undoped layer 19 is 0.15 or more and 0.4 or less.

The expression “graded band-gap energies across the thickness of the undoped layer 19” represents a monotonic increase in band-gap energy in the undoped layer 19 from the light-emitting layer 17 toward the p-type nitride semiconductor layer 27.

The thickness of the undoped layer 19 in FIG. 4 is preferably 0.5 nm or more and 20 nm or less. When the thickness of the undoped layer 19 is 0.5 nm or more, the diffusion of the p-type dopant is effectively prevented, and the p-dopant diffusion distance d₁ is short. This gives the nitride-semiconductor light-emitting element 1 even better temperature characteristic. When the thickness of the undoped layer 19 is 20 nm or less, the drive voltage of the nitride-semiconductor light-emitting element 1 is further reduced. It is more preferred that the undoped layer 19 in FIG. 4 have a thickness of 1 nm or more and 15 nm or less.

<Relationship between the Thickness of the First Barrier Layer and the Undoped Layer>

As mentioned above, in the nitride-semiconductor light-emitting element 1, the thickness t_{L} of the first barrier layer 17BL is equal to or smaller than the thickness t_{N} of the secondary barrier layers 17B. This gives the nitride-semiconductor light-emitting element 1 enhanced emission efficiency and reduced drive voltage. These advantages are significant when the thickness t_{L} of the first barrier layer 17BL is smaller than the thickness t_{N} of the secondary barrier layers 17B.

The details are as follows. The main source of light in the light-emitting layer 17 is the first quantum well layer 17AL. Thus, increasing the efficiency in light emission in the first quantum well layer 17AL leads to enhancing the emission efficiency of the nitride-semiconductor light-emitting element 1. The energy diagrams in FIGS. 2 to 4 neglect piezoelectric field effects, but in reality, the energy bands are curved because of piezoelectric field effects. The degrees of the bends in energy bands influence the emission efficiency of the nitride-semiconductor light-emitting element 1. The energy band structure of the first quantum well layer 17AL is greatly influenced by the p-type nitride semiconductor layer 27, and the magnitude of influence depends on the thickness t_{L} of the first barrier layer 17BL.

Specifically, the band bending due to a piezoelectric field at the first barrier layer 17BL is smaller than that at the secondary barrier layers 17B when the thickness t_{L} of the first barrier layer 17BL is equal to or smaller than the thickness t_{N} of the secondary barrier layers 17B. This improves the efficiency in hole injection from the p-type nitride semiconductor layer 27 into the first quantum well layer 17AL and the secondary quantum well layers 17A, giving the nitride-semiconductor light-emitting element 1 enhanced emission efficiency and reduced drive voltage. These advantages become more significant with decreasing thickness t_{L} of the first barrier layer 17BL. For example, the thickness t_{L} of the first barrier layer 17BL is preferably 0.1 times or more and 1 time or less the thickness t_{N} of the secondary barrier layers 17B.

A small thickness t_{L} of the first barrier layer 17BL would result in impaired temperature characteristic of the nitride-semiconductor light-emitting element 1 by allowing the p-type dopant to diffuse. The nitride-semiconductor light-emitting element 1, however, has an undoped layer 19 between the first barrier layer 17BL and the p-type nitride semiconductor layer 27. It prevents the p-type dopant from diffusing, thereby giving the nitride-semiconductor light-emitting element 1 enhanced temperature characteristic. As a result, the emission efficiency and temperature characteristic of the nitride-semiconductor light-emitting element 1 are enhanced.

The important characteristics of nitride-semiconductor light-emitting element for applications such as general lighting and backlighting include, besides high emission efficiency, stability of the emission efficiency upon heating of the nitride-semiconductor light-emitting element (good temperature characteristic). The nitride-semiconductor light-emitting element 1 offers high emission efficiency, a superior temperature characteristic, and furthermore low drive voltage. These make the nitride-semiconductor light-emitting element 1 usable for applications such as general lighting and backlighting.

### <P-Type Nitride Semiconductor Layer>

Each of the first p-type nitride semiconductor layer 21, the second p-type nitride semiconductor layer 23, and the third p-type nitride semiconductor layer 25 is preferably a p-doped Alₐ₅Ga_{b5}In_{c5}N (0<a5<1, 0<b5<1, 0≦c5<1, and a5+b5+c5=1) layer, more preferably a p-doped Alₐ₅Ga₁₋ₐ₅N (0<a5≦0.4, even more preferably 0.1≦a5≦0.3) layer.

The p-type dopant can be of any kind, but an example is magnesium. In each of the first p-type nitride semiconductor layer 21, the second p-type nitride semiconductor layer 23, and the third p-type nitride semiconductor layer 25 the p-type dopant can be present in any concentration, but preferably 1×10¹⁸ cm⁻³ or more and 2×10²⁰cm⁻³ or less.

Each of the first p-type nitride semiconductor layer 21, the second p-type nitride semiconductor layer 23, and the third p-type nitride semiconductor layer 25 can have any thickness, but preferably 3 nm or more and 200 nm or less.

It is more preferred that the first p-type nitride semiconductor layer 21 be an Alₐ₅Ga₁₋ₐ₅N (0<a5≦0.4, even more preferably 0.1≦a5≦0.3) layer doped with 8×10¹⁸ cm⁻³ or more and 1×10²⁰ cm⁻³ of Mg with a thickness of 5 nm or more and 30 nm or less. In this case, the second p-type nitride semiconductor layer 23 is preferably a GaN layer doped with 8×10¹⁸ cm⁻³ or more and 1×10²⁰ cm⁻³ or less of Mg. This makes holes injected into the light-emitting layer 17 with a higher concentration, thereby giving the nitride-semiconductor light-emitting element 1 further enhanced emission efficiency.

When the second p-type nitride semiconductor layer 23 is a p-type GaN layer, the third p-type nitride semiconductor layer 25 is preferably a GaN layer doped with a higher concentration of Mg than the second p-type nitride semiconductor layer 23. This makes the contact between the electrode on the top surface of the third p-type nitride semiconductor layer 25 (the p-side electrode 33) and the third p-type nitride semiconductor layer 25 less resistive and, furthermore, prevents Mg from diffusing into the light-emitting layer 17.

As illustrated in FIGS. 2 to 4, it is preferred that the first p-type nitride semiconductor layer 21 have a first lower doped layer 21D on the top surface of the undoped layer 19 and a first upper undoped layer 21U on the top surface of the first lower doped layer 21D. In this case, the second p-type nitride semiconductor layer 23 preferably has a second lower undoped layer 23U on the top surface of the first upper undoped layer 21U and a second upper doped layer 23D on the top surface of the second lower undoped layer 23U.

When the first p-type nitride semiconductor layer 21 and the second p-type nitride semiconductor layer 23 have different Al compositions, doping at least one of the first p-type nitride semiconductor layer 21 and the second p-type nitride semiconductor layer 23 with a p-type dopant can cause the concentration of the p-type dopant to be very high at the interface between the first p-type nitride semiconductor layer 21 and the second p-type nitride semiconductor layer 23, so high that the interface is highly resistive. When the first p-type nitride semiconductor layer 21 and the second p-type nitride semiconductor layer 23 have a first upper undoped layer 21U and a second lower undoped layer 23U, respectively, with the first upper undoped layer 21U in contact with the second lower undoped layer 23U, the concentration of the p-type dopant is not very high at the interface between the first p-type nitride semiconductor layer 21 and the second p-type nitride semiconductor layer 23 (i.e., the interface between the first upper undoped layer 21U and the second lower undoped layer 23U), not so high as to make the interface highly resistive.

The first lower doped layer 21D is preferably a p-doped Alₐ₅Ga_{b5}In_{c5}N (0.1≦a5≦0.4, 0.6≦b5≦0.9, 0≦c5≦0.1, and a5+b5+c5=1) layer with a thickness of 2 nm or more and 50 nm or less. The first upper undoped layer 21U is preferably a layer of the same material as the first lower doped layer 21D, although free of p-type dopants, with a thickness of 0 nm or more and 15 nm or less.

The second upper doped layer 23D is preferably a p-doped Alₐ₅Ga_{b5}In_{c5}N (0≦a5≦0.3 (more preferably 0<a5≦0.3), 0.7≦b5≦1 (more preferably 0.7≦b5<1), 0≦c5≦0.1, and a5+b5+c5=1) layer with a thickness of 5 nm or more and 100 nm or less. The second lower undoped layer 23U is preferably a layer of the same material as the second upper doped layer 23D, although free of p-type dopants, with a thickness of 0 nm or more and 30 nm or less.

The first p-type nitride semiconductor layer 21, the second p-type nitride semiconductor layer 23, and the third p-type nitride semiconductor layer 25 may share the same composition or may have different compositions. The thickness may be the same or vary from layer to layer.

### <N-Side Electrode, Transparent Electrode, P-Side Electrode, and Transparent Protection Film>

The n-side electrode 29 and the p-side electrode 33 are used to supply drive power to the nitride-semiconductor light-emitting element 1. Each of the n-side electrode 29 and the p-side electrode 33 is preferably composed of nickel, platinum, and gold layers stacked in this order. The thickness of each of the n-side electrode 29 and the p-side electrode 33 is preferably 300 nm or more and 3000 nm or less.

The transparent electrode 31 is preferably made of a material such as ITO (Indium Tin Oxide) or IZO (Indium Zinc Oxide). The thickness of the transparent electrode 31 is preferably 50 nm or more and 500 nm or less. The transparent electrode 31 may be replaced with a reflective electrode such as an aluminium or silver electrode.

The transparent protection film 35 is preferably a film of SiO₂. The transparent protection film 35 primarily covers the top surface of the transparent electrode 31, the top surface of the second n-type nitride semiconductor layer 11, and the sides of the layers from the second n-type nitride semiconductor layer 11 to the transparent electrode 31.

### [Production of the Nitride-Semiconductor Light-Emitting Element]

The production of the nitride-semiconductor light-emitting element 1 can be, for example, as follows. First, the following layers are formed in order on the top surface of a substrate 3 that has projections 3A alternating with recesses 3B: a buffer layer 5, an underlying layer 7, a first n-type nitride semiconductor layer 9, a second n-type nitride semiconductor layer 11, a superlattice layer 15, a light-emitting layer 17, an undoped layer 19, a first p-type nitride semiconductor layer 21, a second p-type nitride semiconductor layer 23, and a third p-type nitride semiconductor layer 25. These layers are preferably formed using MOCVD (Metal Organic Chemical Vapor Deposition).

It is preferred that the carrier gas be H₂ gas in growing at least part of each of the barrier layers. This gives the barrier layers a higher crystallographic quality, thereby preventing crystallographic defects (crystallographic defects cause failed light emission) from occurring in the barrier layers. As a result, the emission efficiency of the nitride-semiconductor light-emitting element 1 is further enhanced.

In particular, it is preferred that the carrier gas be H₂ gas in growing at least part of the first barrier layer 17BL. Not only does this give the barrier layers a higher crystallographic quality, but also it provides further prevention of the diffusion of the p-dopant.

Then the p-dopant is activated through heating, followed by etching of the third p-type nitride semiconductor layer 25, the second p-type nitride semiconductor layer 23, the first p-type nitride semiconductor layer 21, the undoped layer 19, the light-emitting layer 17, the superlattice layer 15, and the second n-type nitride semiconductor layer 11. An n-side electrode 29 is formed on the surface of the second n-type nitride semiconductor layer 11 exposed through this process of etching. A transparent electrode 31 and a p-side electrode 33 are formed on the top surface of the third p-type nitride semiconductor layer 25 in order. The resulting structure is diced into chips, optionally after heating for alloying. In this way, nitride-semiconductor light-emitting element 1 is obtained.

### [Overall Summary of Embodiments]

The nitride-semiconductor light-emitting element 1 in FIG. 1 includes an n-type nitride semiconductor layer 13, a p-type nitride semiconductor layer 27, and a light-emitting layer 17 between the n-type nitride semiconductor layer 13 and the p-type nitride semiconductor layer 27. The light-emitting layer 17 has one or more quantum well layers and two or more barrier layers, with the quantum well layer(s) lying between the barrier layers. A first barrier layer 17BL, which is the closest of the two or more barrier layers to the p-type nitride-semiconductor layer 27, has a thickness equal to or smaller than that of the barrier layer(s) different from the first barrier layer 17BL (secondary barrier layer(s) 17B). There is an undoped layer 19, a layer of a nitride semiconductor represented by a general formula AlₛGaₜInᵤN (0<s<1, 0<t<1, 0≦u<1, and s+t+u=1), between the first barrier layer 17BL and the p-type nitride-semiconductor layer 27.

When the thickness of the first barrier layer 17BL is equal to or smaller than that of the secondary barrier layer(s) 17B, the band bending due to a piezoelectric field at the first barrier layer 17BL is smaller than that at the secondary barrier layer(s) 17B. This improves the efficiency in hole injection from the p-type nitride semiconductor layer 27 into the quantum well layers. As a result, the emission efficiency is improved, and the drive voltage is lowered.

Furthermore, the undoped layer 19 serves to preserve good temperature characteristic. Making the first barrier layer 17BL thinner would promote the diffusion of the p-type dopant into the light-emitting layer 17, but the undoped layer 19 prevents the p-type dopant from diffusing. Having a first barrier layer 17BL with a thickness equal to or smaller than that of the second barrier layer(s) 17B and an undoped layer 19 in this way, the nitride-semiconductor light-emitting element 1 in FIG. 1 combines improved temperature characteristic with improved emission efficiency and lowered drive voltage.

The undoped layer 19 preferably has a greater band-gap energy than the first barrier layer 17BL. This provides effective prevention of the diffusion of the p-type dopant.

The undoped layer 19 preferably includes a layer of a nitride semiconductor having an Al composition of 0.1 or more with a thickness of 1 nm or more. This provides effective prevention of the diffusion of the p-type dopant.

The undoped layer 19 preferably includes two or more layers with different Al compositions. The layer with a higher Al composition makes the prevention of the diffusion of the p-type dopant more effective, and the layer with a lower Al composition fine-tunes the p-dopant diffusion distance d₁. This prevents any voltage rise at the undoped layer 19, thereby further reducing the drive voltage.

The undoped layer 19 preferably has graded Al compositions across the thickness of the undoped layer 19. This makes the band bending due to a piezoelectric field at the first barrier layer 17BL even smaller than that at the secondary barrier layer(s) 17B. The injection of holes from the p-type nitride semiconductor layer 27 into the first quantum well layer 17AL and the secondary quantum well layer(s) 17A becomes even more efficient, thereby giving the nitride-semiconductor light-emitting element 1 further enhanced emission efficiency and even lower drive voltage. In addition to this, the presence of a high-Al-composition region in the undoped layer 19 makes the prevention of the diffusion of the p-type dopant more effective, further enhancing the temperature characteristic.

In the first quantum well layer 17AL, which is the quantum well layer closest to the p-type nitride semiconductor layer 27, it is preferred that the distance d₁ between the midpoint M in the direction of the thickness of the first quantum well layer 17AL and the point X in the first quantum well layer 17AL with a p-type dopant concentration of 1×10¹⁹ cm⁻³ (the p-dopant diffusion distance d₁) be 10 nm or less.

### EXAMPLES

The following describes the present invention in more detail by providing some examples. However, the present invention is not limited to these examples.

### Example 1

### [Production of Nitride-Semiconductor Light-Emitting Element]

In Example 1, nitride-semiconductor light-emitting elements having an energy band diagram illustrated in FIG. 3 were produced. First, a sapphire wafer (100-mm diameter) with a textured top surface was prepared for use as the substrate. An AlN layer (the buffer layer) was formed on the top surface of the wafer by sputtering.

The wafer with the buffer layer thereon was then put into a first MOCVD system. An undoped GaN layer (the underlying layer, 4-μm thick) was grown on the top surface of the buffer layer using TMG (trimethyl gallium) and NH₃ gases as raw-material gases.

After the addition of SiH₄ gas as a dopant gas, an n-type GaN layer (the first n-type nitride semiconductor layer) was grown on the top surface of the underlying layer. The first n-type nitride semiconductor layer was 3 μm thick and contained the n-type dopant in a concentration of ×10¹⁹ cm⁻³.

The wafer was then removed from the first MOCVD system and put into a second MOCVD system. An n-type GaN layer (the second n-type nitride semiconductor layer) was grown on the top surface of the first n-type nitride semiconductor layer with the wafer temperature maintained at 1050° C. The second n-type nitride semiconductor layer was 1.5 μm thick.

A superlattice layer was then grown on the top surface of the second n-type nitride semiconductor layer with the wafer temperature maintained at 880° C. Specifically, Si-doped GaN layers (second semiconductor layers) and Si-doped InGaN layers (first semiconductor layers) were alternately grown for 20 cycles.

The raw-material gases for the first semiconductor layers were TEG, TMI (trimethyl indium), NH₃, and SiH₄ gases. Each first semiconductor layer was 1.75 nm thick. In growing the first semiconductor layers, the TMI flow rate and the growth temperature were adjusted so that the photoluminescence from the first semiconductor layers would have a wavelength of 375 nm. Each first semiconductor layer therefore had a composition of InᵥGa₁₋ᵥN (v=0.10). The carriers were equalized in the superlattice layer by diffusing into the first and second semiconductor layers. Thus, the average carrier concentration in the superlattice layer was approximately 1×10¹⁹ cm⁻³.

The raw-material gases for the second semiconductor layers were TEG, NH₃, and SiH₄ gases. Each second semiconductor layer was 1.75 nm thick and contained Si in a concentration of 1×10¹⁹ cm⁻³.

After the wafer temperature was lowered to 850° C., a light-emitting layer was grown. Specifically, undoped GaN layers (secondary barrier layers) and undoped InGaN (quantum well layers) were alternately grown for 8 cycles.

The raw-material gases for the secondary barrier layers were TEG and NH₃ gases, and the carrier gases were N₂ and H₂ gases. Each secondary barrier layer was grown at a rate of 60 nm/hour and was 4 nm thick.

Each secondary barrier layer was composed of a secondary lower barrier layer (1.3-nm thick) and a secondary upper barrier layer (2.7-nm thick). The secondary lower barrier layers were formed without H₂ gas, and the secondary upper barrier layers were formed with 6% by volume H₂ gas.

After the growth of the secondary barrier layers, the TEG supply was cut off together with the H₂ supply, and only the NH₃ and N₂ gases were passed for 30 seconds. Subsequently, the growth of the quantum well layers was started.

The raw-material gases for the quantum well layers were TMI, TEG, and NH₃ gases, and the carrier gas was N₂ gas. Each quantum well layer was grown at a rate of 40 nm/hour and was 4 nm thick. The TMI flow rate was adjusted so that the photoluminescence from the quantum well layers would have a wavelength of 445 nm. Each quantum well layer therefore had a composition of In_{z}Ga_{1-z}N (z=0.13).

A 4-nm thick undoped GaN layer (the first barrier layer) was grown on the top surface of the first quantum well layer. The first barrier layer was composed of a primary lower barrier layer (1.3-nm thick) and a primary upper barrier layer (2.7-nm thick). The primary lower barrier layer was formed without H₂ gas, and the primary upper barrier layer was formed with 6% by volume H₂ gas.

After the wafer temperature was increased, a first undoped Al_{0.1}Ga_{0.9}N layer (4-nm thick, the first undoped layer) and a second undoped Al_{0.2}Ga_{0.8}N layer (2-nm thick, the second undoped layer) were grown on the top surface of the first barrier layer.

Then a p-type Al_{0.2}Ga_{0.8}N layer (the first p-type nitride semiconductor layer), a p-type GaN layer (the second p-type nitride semiconductor layer), and a p-type contact layer (the third p-type nitride semiconductor layer) were grown on the top surface of the second undoped layer in order.

The following layers were then etched to expose part of the second n-type nitride semiconductor layer: the third, second, and first p-type nitride semiconductor layers, the second and first undoped layers, the light-emitting layer, the superlattice layer, and the second n-type nitride semiconductor layer. A Au n-side electrode was formed on the top surface of the second n-type nitride semiconductor layer exposed through this process of etching. An ITO transparent electrode and a Au p-side electrode were formed on the top surface of the third p-type nitride semiconductor layer in order. Then a SiO₂ transparent protection film was formed, primarily covering the top surface of the transparent electrode, the top surface of the second n-type nitride semiconductor layer, and the sides of the layers exposed through the above etching process.

The wafer was then divided into 430 μm×480 μm chips. In this way, nitride-semiconductor light-emitting elements of this example were fabricated.

### [Evaluation]

A nitride-semiconductor light-emitting element obtained was mounted onto a TO-18 stem and subjected to the measurement of optical power without being sealed with resin.

At a drive current of 50 mA and a drive voltage of 2.9 V, the nitride-semiconductor light-emitting element displayed an optical power of 77 mW (dominant wavelength, 451 nm). This result indicates that the nitride-semiconductor light-emitting element had an external quantum efficiency of 55% when the drive current was 50 mA.

At a drive current of 120 mA and a drive voltage of 3.0 V, the nitride-semiconductor light-emitting element displayed an optical power of 177 mW (dominant wavelength, 451 nm). This result indicates that the nitride-semiconductor light-emitting element had an external quantum efficiency of 52.7% when the drive current was 120 mA.

The percentage of the external quantum efficiency of the nitride-semiconductor light-emitting element at a drive current of 50 mA was therefore 95.8% relative to that at a drive current of 120 mA. An increase in drive current caused little loss of the external quantum efficiency of the nitride-semiconductor light-emitting element, demonstrating that droop was limited.

The percentage of the external quantum efficiency at 100° C. to that at room temperature (hereinafter referred to as “temperature characteristic”) was calculated to be 99%. An increase in temperature therefore caused little loss of the external quantum efficiency of the nitride-semiconductor light-emitting element.

In the In concentration profile in FIG. 6, the midpoint of the first quantum well layer in the direction of thickness (point M) corresponds to the position of the first In ion intensity peak of the first quantum well layer on the p-type nitride semiconductor layer side. The distance d₁ between point M as determined in this way and point X, the point in the first quantum well layer where the p-type dopant concentration was 1×10¹⁹ cm⁻³, (p-dopant diffusion distance d₁) was 1.5 nm.

### Examples 2 to 5

In Examples 2 to 5, the first and second undoped layers were as specified in Table 1 in producing nitride-semiconductor light-emitting elements. Except for this, the method described in Example 1 above was followed to produce the nitride-semiconductor light-emitting elements.

TABLE 1

| | First undoped layer | | Second undoped layer | |
|---|---|---|---|---|
| | Al composition | Thickness | Al composition | Thickness |
| | (%) | (nm) | (%) | (nm) |
| Example 2 | 8 | 4 | 5 | 2 |
| Example 3 | 8 | 4 | 8 | 2 |
| Example 4 | 8 | 4 | 10 | 2 |
| Example 5 | 8 | 4 | 15 | 2 |

FIG. 7 illustrates the relationship between the Al composition of the second undoped layer and the temperature characteristic. As illustrated in FIG. 7, the nitride-semiconductor light-emitting element displayed even better temperature characteristics at the Al compositions of the second undoped layer of 10% (0.1) or more than at the Al compositions of the second undoped layer of less than 10% (0.1). It is therefore preferred that the Al composition of the second undoped layer be 10% (0.1) or more.

### Examples 6 to 9

In Examples 6 to 9, the first and second undoped layers were as specified in Table 2 in producing nitride-semiconductor light-emitting elements. Except for this, the method described in Example 1 above was followed to produce the nitride-semiconductor light-emitting elements.

TABLE 2

| | First undoped layer | | Second undoped layer | |
|---|---|---|---|---|
| | Al composition | Thickness | Al composition | Thickness |
| | (%) | (nm) | (%) | (nm) |
| Example 6 | 8 | 4 | 15 | 0.5 |
| Example 7 | 8 | 4 | 15 | 1 |
| Example 8 | 8 | 4 | 15 | 2 |
| Example 9 | 8 | 4 | 15 | 4 |

FIG. 8 illustrates the relationship between the thickness of the second undoped layer and the temperature characteristic. As illustrated in FIG. 8, the nitride-semiconductor light-emitting element displayed even better temperature characteristics at the thicknesses of the second undoped layer of 1 nm or more than at the thickness of the second undoped layer of less than 1 nm. It is therefore preferred that the undoped layer with an Al composition of 10% (0.1) or more have a thickness of 1 nm or more.

### Example 10

In Example 10, nitride-semiconductor light-emitting elements having an energy band diagram illustrated in FIG. 2 were produced. That is, the first and second undoped layers were replaced with an undoped AlGaN layer (5-nm thick) with an Al composition of 16% (0.16). This example achieved external quantum efficiency values and a temperature resistance similar to those in Example 1 above.

### Example 11

In Example 11, nitride-semiconductor light-emitting elements having an energy band diagram illustrated in FIG. 4 were produced. That is, an undoped layer (6-nm thick) was formed in which the Al composition was graded in the direction from the top surface of the first barrier layer toward the first p-type nitride semiconductor layer, from 10% (0.1) to 18% (0.18). This example achieved external quantum efficiency values and a temperature resistance similar to those in Example 1 above.

### Examples 1, 12, 13 and Comparative Examples 1 and 2

In Examples 12 and 13 and Comparative Examples 1 and 2, the first and second undoped layers were as specified in Table 3 in producing nitride-semiconductor light-emitting elements. Except for this, the method described in Example 1 above was followed to produce the nitride-semiconductor light-emitting elements.

A nitride-semiconductor light-emitting element obtained was subjected to the measurement of optical power at a drive current of 50 mA and a drive voltage of 2.9 V. From the result, the external quantum efficiency of the nitride-semiconductor light-emitting element at a drive current of 50 mA was determined.

TABLE 3

| | First | Secondary | First | | |
|---|---|---|---|---|---|
| | barrier | barrier | undoped | | External |
| | layer | layer | layer | Total | quantum |
| | thickness | thickness | thickness | thickness | efficiency |
| | (nm) | (nm) | (nm) | (nm)*³¹ | (%)*³² |
| Example 12 | 2 | 4 | 6 | 8 | 56 |
| Example 13 | 3 | 4 | 5 | 8 | 56 |
| Example 1 | 4 | 4 | 4 | 8 | 55 |
| Comparative | 5 | 4 | 3 | 8 | 53 |
| Example 1 | | | | | |
| Comparative | 7 | 4 | 1 | 8 | 50 |
| Example 2 | | | | | |

In Table 3, “Total thickness (nm)*³¹” represents the sum of the thickness of the first barrier layer and that of the first undoped layer, and “External quantum efficiency (%)*³²”represents the external quantum efficiency of the nitride-semiconductor light-emitting element at a drive voltage of 50 mA.

As illustrated in Table 3, the nitride-semiconductor light-emitting element displayed higher external quantum efficiencies with decreasing thickness of the first barrier layer. In particular, the nitride-semiconductor light-emitting element with a first barrier layer thinner than the secondary barrier layers (4 nm) exhibited very high external quantum efficiencies. It is therefore more preferred that the first barrier layer be thinner than the secondary barrier layer(s).

### Example 14

In Example 14, nitride-semiconductor light-emitting elements having an energy band diagram illustrated in FIG. 9 were produced. That is, the first and second undoped layers were replaced with an undoped AlGaN layer (4-nm thick) with an Al composition of 20% (0.2). Except for this, the method described in Example 1 above was followed to produce the nitride-semiconductor light-emitting elements.

This example differed from Example 10 above only in the Al composition and thickness of the undoped layer. Nevertheless, this example achieved a further improvement in the performance of nitride-semiconductor light-emitting element and productivity compared with Example 10 above. This may be explained as follows.

In this example, the Al composition of the undoped layer was 20% (0.2). The undoped layer therefore had the same Al composition as the p-type Al_{0.2}Ga_{0.8}N layer (first p-type nitride semiconductor layer) grown on its top surface. It was not needed to discontinue growth to change the flow rate of TMA (trimethyl aluminium) gas between the growth of the undoped layer and that of the p-type Al_{0.2}Ga_{0.8}N layer. The workpiece was therefore held at high temperatures only for a short time. The above results appear to be due to these facts.

### Example 15

In Example 15, nitride-semiconductor light-emitting elements having an energy band diagram illustrated in FIG. 3 were produced, but the primary and secondary barrier layers contained Al. They were AlGaN layers with an Al composition of 0.2% (0.002). When the primary and secondary barrier layers are AlGaN layers (Al composition, 0.2% (0.002)), the band-gap energy of the primary and secondary barrier layers is close to that of the undoped layer. The band bending due to a piezoelectric field at the first barrier layer in this example is therefore smaller than that in Example 1 above. As a result, this example achieved a further improvement in emission efficiency compared with Example 1 above. Furthermore, the primary and secondary barrier layers successfully prevented the diffusion of Mg compared with those in Example 1 above by virtue of their being AlGaN layers with an Al composition of 0.2% (0.002). This led to further improved temperature characteristic as compared with that in Example 1 above.

### Example 16

In Example 16, the composition of the quantum well layers was adjusted to make the emission wavelength 405 nm, and the primary and secondary barrier layers were AlGaN layers with an Al composition of 3% (0.03). Except for these, the method described in Example 1 above was followed to produce nitride-semiconductor light-emitting elements. Even with the emission wavelength in the near-ultraviolet region, the nitride-semiconductor light-emitting element displayed improved performance.

The embodiments and examples disclosed herein should be construed as being exemplary in all respects rather than being limiting. The scope of the present invention is defined not by the foregoing description but by the claims and is intended to include equivalents to the scope of the claims and all modifications that fall within the scope of the claims.

### REFERENCE SIGNS LIST

1 Nitride-semiconductor light-emitting element; 3 Substrate; 3A Projection; 3B Recess; 5 Buffer layer; 7 Underlying layer; 9 First n-type nitride-semiconductor layer; 11 Second n-type nitride-semiconductor layer; 13 N-type nitride-semiconductor layer; 15 Superlattice layer; 15A First semiconductor layer; 15B Second semiconductor layer; 17 Light-emitting layer; 17A Secondary quantum well layer; 17AL First quantum well layer; 17B Secondary barrier layer; 17BL First barrier layer; 19 Undoped layer; 19A First undoped layer; 19B Second undoped layer; 21 First p-type nitride-semiconductor layer; 21D First lower doped layer; 21U First upper undoped layer; 23 Second p-type nitride-semiconductor layer; 23D Second upper doped layer; 23U Second lower undoped layer; 25 Third p-type nitride-semiconductor layer; 27 P-type nitride-semiconductor layer; 29 N-side electrode; 31 Transparent electrode; 33 P-side electrode; 35 Transparent protection film.

1. A nitride-semiconductor light-emitting element comprising an n-type nitride-semiconductor layer, a p-type nitride-semiconductor layer, and a light-emitting layer between the n-type and p-type nitride-semiconductor layers, wherein:
the light-emitting layer has one or more quantum well layers and two or more barrier layers, the quantum well layer or layers lying between the barrier layers;
a first barrier layer, which is a closest of the two or more barrier layers to the p-type nitride-semiconductor layer, has a thickness smaller than a thickness of the barrier layer or layers different from the first barrier layer; and
there is an undoped layer between the first barrier layer and the p-type nitride-semiconductor layer in order, the undoped layer being a layer of a nitride semiconductor represented by a general formula AlₛGaₜInᵤN (0<s<1, 0<t<1, 0≦u<1, and s+t+u=1).

2. The nitride-semiconductor light-emitting element according to claim 1, wherein the undoped layer has a greater band-gap energy than the first barrier layer.

3. The nitride-semiconductor light-emitting element according to claim 1, wherein the undoped layer includes a layer of a nitride semiconductor having an Al composition of 0.1 or more with a thickness of 1 nm or more.

4. The nitride-semiconductor light-emitting element according to claim 1, wherein the undoped layer includes two or more layers with different Al compositions.

5. The nitride-semiconductor light-emitting element according to claims 1, wherein the undoped layer has graded Al compositions across a thickness thereof.

6. The nitride-semiconductor light-emitting element according to claim 1, wherein the p-type nitride-semiconductor layer is a layer doped with p-type dopant, the quantum well layer is undoped InₓGa₍₁₋ₓ₎N (0<x≦1) layer, and p-type dopant is diffused through said undoped layer from said p-type nitride-semiconductor layer to said light-emitting layer, and wherein in a first quantum well layer, which is a quantum well layer closest to the p-type nitride-semiconductor layer, a distance between a midpoint M in a direction of a thickness of the first quantum well layer and a point in the first quantum well layer with a p-type dopant concentration of 1×10¹⁹ cm⁻³ is 10 nm or less.
